(19) United States
(12) Patent Application Publication
(10) Pub. No.: US 2008/0093657 A1
(43) Pub. Date: Apr. 24, 2008

(54) Nonvolatile memory devices and methods of fabricating the same

(76) Inventors: Ho-Min Son, Suwon-si (KR); Yong-Woo Hyung, Yongin-si (KR); Won-Jun Jang, Seoul (KR); Jung-Geun Jee, Seoul (KR); Hyoeng-Ki Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/653,346

(22) Filed: Jan. 16, 2007

(30) Foreign Application Priority Data
Oct. 20, 2006 (KR) 2006-102580

(51) Int. Cl. H01L 29/788

(52) U.S. Cl. 257/321

(57) ABSTRACT

A method of fabricating a nonvolatile memory device includes forming at least one insulating layer on at least one of a semiconductor substrate and a layer including a semi-conductive material, and performing a plasma process using fluorine on the semiconductor. In some cases, an interface between the insulating layer and the semiconductor substrate includes fluorine.

### BACKGROUND OF THE INVENTION

1. Field of the Invention

The present invention disclosed herein relates to a semiconductor device and a method of fabricating the same. More particularly, the present invention relates to a nonvolatile memory device and a method of fabricating the same.

2. Description of the Related Art

In general, semiconductor memory devices are classified into volatile memory devices and nonvolatile memory devices. Volatile memory devices need a power supply to retain data, while the nonvolatile memory devices can retain data without power. A flash memory device is a highly-integrated nonvolatile memory device that is developed to have the advantages of an erasable programmable read only memory (EPROM) and the advantages of an electrically erasable programmable read only memory (EEPROM).

The flash memory device has a tunnel insulating layer between a semiconductor substrate and a floating gate layer. The tunnel insulating layer is formed through a thermal oxidation process using oxygen gas and hydrogen gas as source gas. In addition, processes using hydrogen gas are performed after the forming of the tunnel insulating layer. Accordingly, an interface between the tunnel insulating layer and the semiconductor substrate contains hydrogen. The hydrogen at the interface between the tunnel insulating layer and the semiconductor substrate may be bonded with silicon atoms and may degrade reliability of the tunnel insulating layer.

### SUMMARY OF THE INVENTION

The present invention is therefore directed to nonvolatile memory devices, which substantially overcome one or more of the problems due to limitations and disadvantages of the related art.

It is therefore a feature of an embodiment of the present invention to provide a nonvolatile memory device with improved reliability.

It is therefore a separate feature of an embodiment of the invention to provide a method of fabricating a nonvolatile memory device with improved reliability.

At least one of the above and other features and advantages of the present invention may be realized by providing a method of fabricating a nonvolatile memory device, the method comprising forming at least one insulating layer on at least one of a semiconductor substrate and a layer including a semi-conductive material, and performing a plasma process using fluorine on the semiconductor substrate.

The insulating layer may be a tunnel insulating layer disposed on the semiconductor substrate. The plasma process may be performed after the forming of the tunnel insulating layer. The method may further include performing a thermal treatment process on the semiconductor substrate after performing the plasma process. The tunnel insulating layer may be formed after performing the plasma process on the semiconductor substrate.

The method may further include performing a thermal treatment process on the semiconductor substrate after performing the plasma process. The semi-conductive material may be polysilicon. Forming at least one insulating layer may include forming a tunnel insulating layer disposed on the semiconductor substrate, and forming an interlayer insulating layer. The method may further include forming the semi-conductive material on the tunnel insulating layer, and the semi-conductive material may serve as a charge storage layer. Performing the plasma process employing fluorine may occur before forming the interlayer insulating layer.

The method may include performing a thermal treatment process on the semiconductor substrate after performing the plasma process. Performing the plasma process using fluorine may occur after forming the interlayer insulating layer. The method may further include performing a thermal treatment process on the semiconductor substrate after performing the plasma process. The method may include forming a gate electrode on the interlayer insulating layer.

At least one of the above and other features and advantages of the present invention may be separately realized by providing a nonvolatile memory device including a tunnel insulating pattern disposed on a semiconductor substrate, a charge storage pattern disposed on the tunnel insulating pattern, an interlayer insulating pattern disposed on the charge storage pattern, and a gate electrode disposed on the interlayer insulating pattern, wherein an interface between the semiconductor substrate and the tunnel insulating pattern contains fluorine.

The gate electrode may include one of a polysilicon and tantalum nitride (TaN). The interlayer insulating pattern may include a first oxide layer pattern disposed on the charge storage pattern, a nitride layer pattern disposed on the first oxide layer pattern, and a second oxide layer disposed on the nitride layer pattern, wherein at least one of an interface between the charge storage pattern and the first oxide layer pattern, an interface between the first oxide layer pattern and the nitride layer pattern, and an interface between the nitride layer pattern and the second oxide layer pattern may include fluorine.

The interlayer insulting pattern may include an aluminum oxide layer that serves as a blocking insulating layer. The device may include a metal silicide pattern on the gate electrode. The metal silicide pattern may include one of cobalt silicide and tungsten silicide.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A through 1C illustrate cross-sectional views of stages in a method of fabricating a nonvolatile memory device according to a first exemplary embodiment of one or more aspects of the present invention;

FIGS. 2A through 2C illustrate cross-sectional views of stages in a method of fabricating a nonvolatile memory device according to a second exemplary embodiment of one or more aspects of the present invention;

FIGS. 3A through 3C illustrate cross-sectional views of stages in a method of fabricating a nonvolatile memory device according to a third exemplary embodiment of one or more aspects of the present invention; and

FIG. 4 illustrates a cross-sectional view of a nonvolatile memory device according to one or more aspects of the present invention.

### DETAILED DESCRIPTION OF THE INVENTION

Korean Patent Application No. 2006-102580, filed on Oct. 20, 2006, in the Korean Intellectual Property Office, and entitled: “Nonvolatile Memory Device and Method of Fabricating the Same,” is incorporated by reference herein in its entirety.

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout the specification.

Hereinafter, an exemplary embodiment of the present invention will be described with reference to the accompanying drawings.

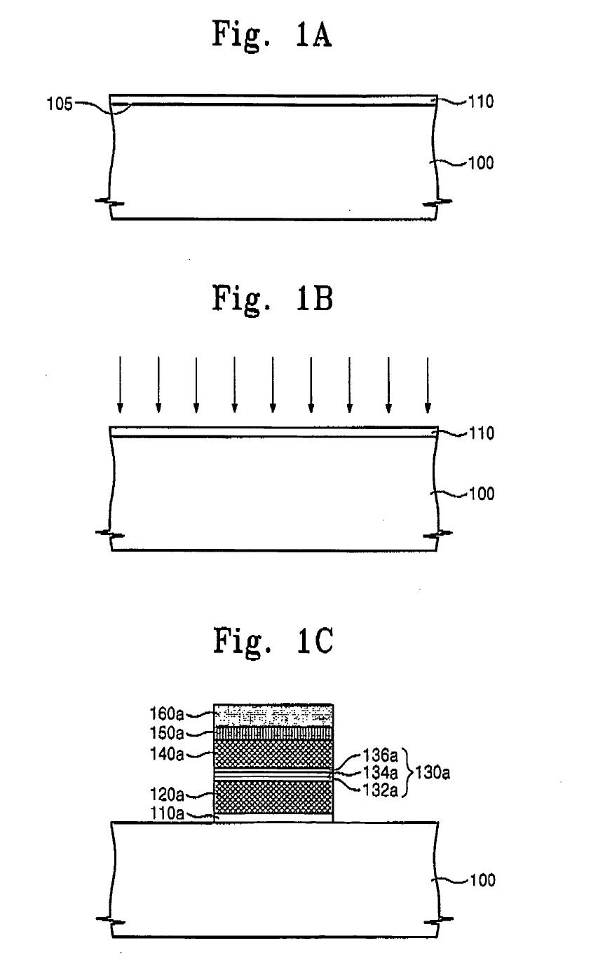

FIGS. 1A through 1C illustrate cross-sectional views of stages in a method of fabricating a nonvolatile memory device according to a first exemplary embodiment of one or more aspects of the present invention.

Referring to FIG. 1A, a tunnel insulating layer 110 may be formed on a semiconductor substrate 100. The tunnel insulating layer 110 may include, e.g., a silicon oxide layer that may be formed by, e.g., a thermal oxidation process. The tunnel insulating layer 110 may be formed using, e.g., oxygen gas and hydrogen gas as source gas. However, embodiments of the invention are not limited to a source gas including oxygen gas and hydrogen gas. For example, in some other embodiments, a source gas for forming the tunnel insulating layer 110 may not include a hydrogen-containing gas; however, hydrogen may be used in a subsequent process. If a hydrogen containing gas is employed, the tunnel insulating layer 110 may contain a silicon-hydrogen (Si—H) bond. The Si—H bond at an interface 105 between the tunnel insulating layer 110 and the semiconductor substrate 100 may degrade reliability of the nonvolatile memory device.

Referring to FIG. 1B, a plasma process using fluorine (F) may be performed on the semiconductor substrate 100. Although not shown, the plasma process may be performed before forming the tunnel insulating layer 110 or, as shown in FIG. 1B, may be performed after forming the tunnel insulating layer 110. Through the plasma process, fluorine may be provided to the tunnel insulating layer 110. A thermal treatment process may be performed after performing the plasma process. The thermal treatment process may be performed at temperatures of about 600° C. or more. The thermal treatment process may be replaced with a subsequent high-temperature process. Through the thermal treatment process or the high-temperature process, the fluorine provided to the tunnel insulating layer 110 may be substituted for the hydrogen at the interface 105 between the tunnel insulating layer 110 and the semiconductor substrate 100.

Si—H bond energy is 3.1 eV, and Si—F bond energy is 5.73 eV. Thus, a Si—F bond is stronger and more stable than a Si—H bond. Therefore, fluorine can be substituted for hydrogen through the thermal treatment process or the high-temperature process. In addition, a dangling bond at the interface between the tunnel insulating layer 110 and the semiconductor substrate 100 can be reduced by the fluorine. Reduction of the Si—H bond or the dangling bond can improve the reliability of the nonvolatile memory device.

Next, a charge storage layer (not shown), an interlayer insulating layer (not shown), a gate conductive layer (not shown), a metal silicide layer (not shown) and a hard mask layer (not shown) may be sequentially formed on the tunnel insulating layer 110. The charge storage layer and the gate conductive layer may include, e.g., a polysilicon layer that may be formed by, e.g., chemical vapor deposition (CVD). That is, the charge storage layer and the gate conductive layer may function as a floating gate layer and a control gate layer, respectively.

A photoresist pattern (not shown) may be formed on the hard mask layer. Using the photoresist pattern as an etch mask, an etching process may be performed to form a hard mask pattern 160a. Using the hard mask pattern 160a as an etch mask, an etching process may be performed to sequentially form a metal silicide pattern 150a, a gate electrode 140a, an interlayer insulating pattern 130a, a charge storage pattern 120a and a tunnel insulating pattern 110a. The interlayer insulating pattern 130a may include a first oxide layer pattern 132a, a nitride layer pattern 134a and a second oxide layer pattern 136a, which may be stacked on each other.

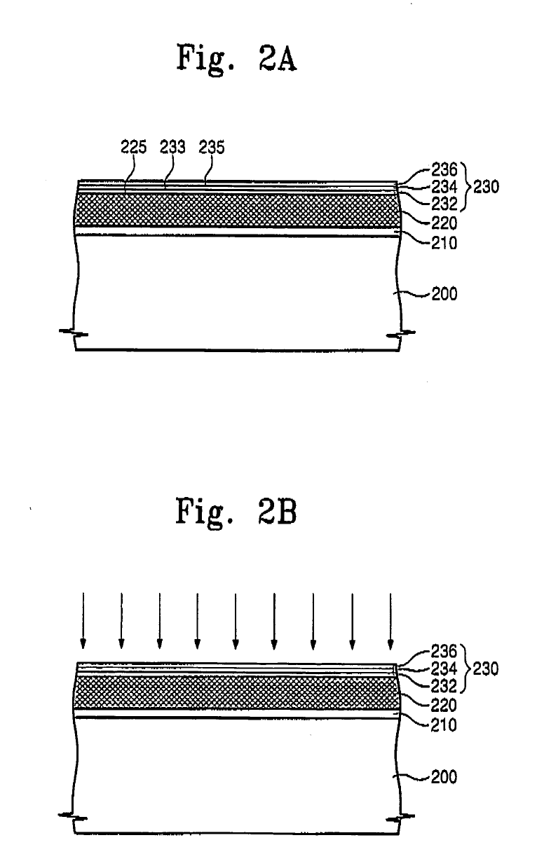

FIGS. 2A through 2C illustrate cross-sectional views of stages in a method of fabricating a nonvolatile memory device according to a second exemplary embodiment of one or more aspects of the present invention.

Referring to FIG. 2A, in the second exemplary embodiment, a tunnel insulating layer 210 may be formed on a semiconductor substrate 200. The tunnel insulating layer 210 may be formed by, e.g., a thermal oxidation process. A charge storage layer 220 may be formed on the tunnel insulating layer 210. The charge storage layer 220 may include a floating gate layer and may include, e.g., polysilicon. An interlayer insulating layer 230 may be formed on the charge storage layer 220. The interlayer insulating layer 230 may be formed by, e.g., CVD. The interlayer insulating layer 130 may include a first oxide layer 232, a nitride layer 234, and a second oxide layer 236. Si—H bond(s) may exist at, e.g., an interface 225 between the charge storage layer 220 and the first oxide layer 232, an interface 233 between the first oxide layer 232 and the nitride layer 234 and/or an interface 235 between the nitride layer 234 and the second oxide layer 236. Such Si—H bond(s) may be the result of hydrogen gas used during formation of the interlayer insulating layer 130 and/or hydrogen-containing gas used during a subsequent process.

Referring to FIG. 2B, a plasma process using fluorine (F) may be performed on the semiconductor substrate 200. In some embodiments, e.g., the first exemplary embodiment illustrated in FIGS. 1A and 1B, the plasma process may be performed before forming the interlayer insulating layer 230. Through the plasma process, fluorine may be provided to the interlayer insulating layer 230. A thermal treatment process may be performed after performing the plasma process. The thermal treatment process may be performed at a temperature of 600° C. or more. A subsequent high-temperature process may be employed instead of the thermal treatment process. Through the thermal treatment process or the subsequent high-temperature process, fluorine may be substituted for hydrogen at, e.g., the interface 225 between the charge storage layer 220 and the first oxide layer 232, the interface between the first oxide layer 232 and the nitride layer 234, and/or the interface between the nitride layer 234 and the second oxide layer 236. Thus, the Si—H bond(s) at, e.g., the interface 225 between the charge storage layer 220 and the first oxide layer 232, the interface between the first oxide layer 232 and the nitride layer 234, and/or the interface between the nitride layer 234 and the second oxide layer 236 may be reduced, and reliability of the nonvolatile memory device may be improved.

Referring to FIGS. 2B and 2C, a gate conductive layer (not shown) may be formed on the interlayer insulating layer 230. The gate conductive layer may include a polysilicon layer and the gate conductive layer may be formed by, e.g., CVD. The gate conductive layer may function as a control gate layer. A metal silicide layer and a hard mask layer (not layer) may be sequentially formed on the gate conductive layer.

A photoresist pattern (not shown) may be formed on the hard mask layer. Using the photoresist pattern as an etch mask, an etching process may be performed to form a hard mask pattern 260a. Using the hard mask pattern 260a as an etch mask, an etching process may be performed to sequentially form a metal silicide pattern 250a, a gate electrode 240a, an interlayer insulating pattern 230a, a charge storage pattern 220a, and a tunnel insulating pattern 210a. The interlayer insulating pattern 230a may include a first oxide layer pattern 232a, a nitride layer pattern 234a and a second oxide layer pattern 236a, which may be stacked on each other.

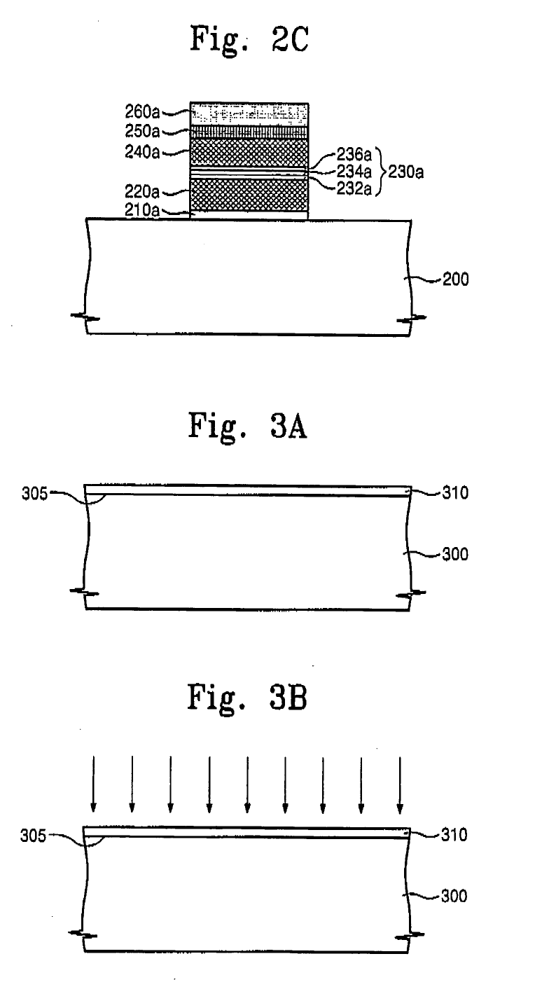

FIGS. 3A through 3C illustrate cross-sectional views of stages in a method of fabricating a nonvolatile memory device according to a third exemplary embodiment of one or more aspects of the present invention.

Referring to FIG. 3A, a tunnel insulating layer 310 may be formed on a semiconductor substrate 300. The tunnel insulating layer 310 may include a silicon oxide layer that may be formed by a thermal oxidation process. An interface 305 between the tunnel insulating layer 310 and the semiconductor substrate 300 may include Si—H bond(s) or dangling bond(s). The Si—H bond(s) and/or the dangling bond(s) may degrade the reliability of the nonvolatile memory device.

Referring to FIG. 3B, a plasma process using fluorine (F) may be performed on the semiconductor substrate 300. In some embodiments, although not shown, the plasma process may be performed before forming the tunnel insulating layer 310. A thermal treatment process may be performed after performing the plasma process. The thermal treatment process may be replaced with a subsequent high-temperature process. Through the thermal treatment process or the subsequent high-temperature process, fluorine provided by the plasma process may be substituted with hydrogen in the Si—H bond(s) and/or may reduce the dangling bond(s).

A charge storage layer (not shown) may be formed on the tunnel insulating layer 310. The charge storage layer may include a silicon nitride layer that may be used as a charge trap layer. An interlayer insulating layer (not shown) may be formed on the charge storage layer. The interlayer insulating layer may include an aluminum oxide (Al₂O₃) layer and may be formed by CVD.

In some embodiments, the plasma process may be performed after forming the interlayer insulating layer and more particularly, e.g., in some embodiments the plasma process may be performed before or after forming the tunnel insulating layer 310 and/or before or after forming the interlayer insulating layer. Through a plasma process, fluorine provided during the plasma process may be substituted for hydrogen and/or may reduce dangling bond(s) at, e.g., the interface 305 between the tunnel insulating layer 310 and the semiconductor substrate 300, an interface 315 between the tunnel insulating layer 310 and the charge storage layer, and an interface 325 between the charge storage layer and the interlayer insulating layer.

A gate conductive layer may be formed on the interlayer insulating layer. The gate conductive layer may include, e.g., a tantalum nitride (TaN) layer and the gate conductive layer may be formed by, e.g., CVD or by sputtering. A hard mask layer may be formed on the gate conductive layer. The hard mask layer may include a silicon nitride layer, and the hard mask layer may be formed by CVD. A photoresist pattern may be formed on the hard mask layer. Referring to FIG. 3C, using the photoresist pattern as an etch mask, an etching process may be performed to form a hard mask pattern 360a. Using the hard mask pattern 360a as an etch mask, an etching process may be performed to sequentially form a gate electrode 340a, an interlayer insulating pattern 330a, a charge storage pattern 320a, and a tunnel insulating pattern 310a. According to the further embodiment of the present invention, the reliability of a charge trap flash memory device can be improved.

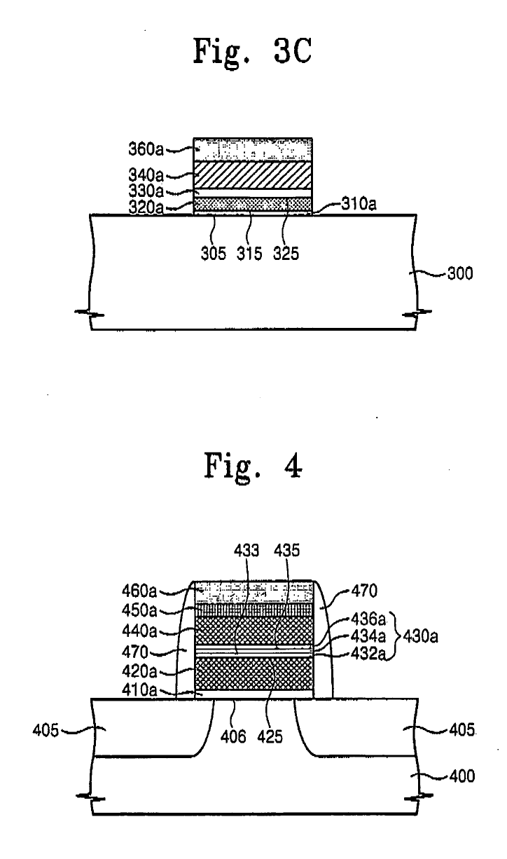

FIG. 4 illustrates a cross-sectional view of a nonvolatile memory device according to one or more aspects of the present invention.

Referring to FIG. 4, a tunnel insulating pattern 410a may be disposed on a semiconductor substrate 400. The tunnel insulating pattern 410a may include a silicon oxide layer. A charge storage pattern 420a may be disposed on the tunnel insulating pattern 410a. The charge storage pattern 420a may include, e.g., a polysilicon layer, and may function as a floating gate layer. The charge storage pattern 420a may include, e.g., a silicon nitride layer, and may function as a charge trap layer. An interlayer insulating pattern 430a may be disposed on the charge storage pattern 420a. The interlayer insulating pattern 430a may include a first oxide layer pattern 432a, a nitride layer pattern 434a and a second oxide layer pattern 436a, which may be stacked on each other. In some other embodiments, e.g., the interlayer insulating pattern 430a may include an aluminum oxide (Al₂O₃) layer, and may function as a blocking insulating layer. A gate electrode 440a may be disposed on the interlayer insulating pattern 430a. The gate electrode 440a may include a polysilicon layer that functions as a control gate layer. Alternatively, the gate electrode 440a may include, e.g., a tantalum nitride (TaN) layer. A metal silicide pattern 450a may be disposed on the gate electrode 440a. The metal silicide pattern 450a may include, e.g., cobalt silicide or tungsten silicide. A hard mask pattern 460a may be disposed on the metal silicide pattern 450a. The hard mask pattern 460a may include, e.g., a silicon nitride layer or a silicon nitride oxide layer. In some embodiments of the invention, a gate pattern of the nonvolatile memory device may include the hard mask pattern 460a, the metal silicide pattern 450a, the gate electrode 440a, the interlayer insulating pattern 430a, the charge storage pattern 420a, and the tunnel insulating pattern 410a.

As shown in FIG. 4, spacers 470 may be disposed on sidewalls of the gate pattern. The spacers 470 may include, e.g., a silicon nitride layer. Impurity regions 405 may be disposed in the semiconductor substrate 400 adjacent to the gate pattern. The impurity regions 405 may be source/drain regions.

An interface 406 between the tunnel insulating pattern 410a and the semiconductor substrate 400 may contain fluorine (F). The fluorine at the interface 406 may be a result of a substitution for hydrogen in Si—H bond(s). Embodiments of the invention enable Si—H bond(s) and/or dangling bond(s) at an interface 406 between the tunnel insulating pattern 410a and the semiconductor substrate 400 to be reduced and/or eliminated to improve the reliability of the nonvolatile memory device. An interface 425 between the charge storage pattern 420a and the first oxide layer pattern 432a, an interface 433 between the first oxide layer pattern 132a and the nitride layer pattern 134a, and/or an interface 435 between the nitride layer pattern 134a and the second oxide layer pattern 136a may contain fluorine (F). As a result of substitution of fluorine for the hydrogen and/or reduction of dangling bond(s) by fluorine, fluorine may be present in the charge storage pattern 420a and the interlayer insulating pattern 430a. Accordingly, the reliability of the nonvolatile memory device can be improved.

According to an embodiment of the present invention, Si—H bond(s) and/or dangling bond(s) at an interface between a tunnel insulating layer and a semiconductor substrate can be reduced and/or eliminated.

According to another embodiment of the present invention, Si—H bond(s) and/or dangling bond(s) in a charge storage layer and an interlayer insulating layer can be reduced and/or eliminated.

By reducing and/or eliminating Si—H bond(s) at interfaces between layers of a nonvolatile memory device, reliability of the nonvolatile memory device can be improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a nonvolatile memory device, the method comprising:
forming at least one insulating layer on at least one of a semiconductor substrate and a layer including a semi-conductive material; and
performing a plasma process using fluorine on the semiconductor substrate.

2. The method as claimed in claim 1, wherein the insulating layer is a tunnel insulating layer disposed on the semiconductor substrate.

3. The method as claimed in claim 2, wherein the plasma process is performed after forming the tunnel insulating layer.

4. The method as claimed in claim 3, further comprising performing a thermal treatment process on the semiconductor substrate after performing the plasma process.

5. The method as claimed in claim 2, wherein the tunnel insulating layer is formed after performing the plasma process on the semiconductor substrate.

6. The method as claimed in claim 5, further comprising performing a thermal treatment process on the semiconductor substrate after performing the plasma process.

7. The method as claimed in claim 1, wherein the semi-conductive material is polysilicon.

8. The method as claimed in claim 1, wherein forming at least one insulating layer comprises forming a tunnel insulating layer disposed on the semiconductor substrate, and forming an interlayer insulating layer.

9. The method as claimed in claim 8, wherein the method further comprises forming the semi-conductive material on the tunnel insulating layer, and the semi-conductive material serves as a charge storage layer.

10. The method as claimed in claim 9, wherein performing the plasma process using fluorine occurs before forming the interlayer insulating layer.

11. The method as claimed in claim 10, further comprising performing a thermal treatment process on the semiconductor substrate after performing the plasma process.

12. The method as claimed in claim 9, wherein performing the plasma process using fluorine occurs after forming the interlayer insulating layer.

13. The method as claimed in claim 12, further comprising performing a thermal treatment process on the semiconductor substrate after performing the plasma process.

14. The method as claimed in claim 8, further comprising forming a gate electrode on the interlayer insulating layer.

15. A nonvolatile memory device, comprising:
a tunnel insulating pattern disposed on a semiconductor substrate;
a charge storage pattern disposed on the tunnel insulating pattern;
an interlayer insulating pattern disposed on the charge storage pattern; and
a gate electrode disposed on the interlayer insulating pattern,
wherein an interface between the semiconductor substrate and the tunnel insulating pattern contains fluorine.

16. The nonvolatile memory device as claimed in claim 15, wherein the gate electrode includes one of a polysilicon and tantalum nitride (TaN).

17. The nonvolatile memory device as claimed in claim 15, wherein the interlayer insulating pattern comprises:
a first oxide layer pattern disposed on the charge storage pattern;
a nitride layer pattern disposed on the first oxide layer pattern; and
a second oxide layer disposed on the nitride layer pattern,
wherein at least one of an interface between the charge storage pattern and the first oxide layer pattern, an interface between the first oxide layer pattern and the nitride layer pattern, and an interface between the nitride layer pattern and the second oxide layer pattern includes fluorine.

18. The nonvolatile memory device as claimed in claim 15, wherein the interlayer insulting pattern includes an aluminum oxide layer that serves as a blocking insulating layer.

19. The nonvolatile memory device as claimed in claim 15, further comprising a metal silicide pattern on the gate electrode.

20. The nonvolatile memory device as claimed in claim 19, wherein the metal silicide pattern includes one of cobalt silicide and tungsten silicide.
